(19) United States
(12) Patent Application Publication
(10) Pub. No.: US 2007/0035323 A1
(43) Pub. Date: Feb. 15, 2007

(54) Method for fabricating electronic circuit module and integrated circuit device

(75) Inventors: June-Hyeon Ahn, Suwon-si (KR); Young-Min Lee, Yongin-si (KR); Ho-Seong Seo, Suwon-si (KR); Kyu-Sub Kwak, Seoul (KR)

Correspondence Address: CHA & REITER, LLC, 210 ROUTE 4 EAST STE 103, PARAMUS, NJ, 07652, US

(73) Assignee: Samsung Electronics Co., LTD

(21) Appl. No.: 11/432,064

(22) Filed: May 11, 2006

(30) Foreign Application Priority Data
Aug. 9, 2005 (KR) 2005-72752

(51) Int. Cl. G01R 31/26

(52) U.S. Cl. 324/765

(57) ABSTRACT

An electronic circuit module and its fabricating method are provided. The electronic circuit module includes a first board and a second board having printed circuit patterns formed on the respective surfaces, and an electronic device disposed between the first board and the second board and having electrodes connected to the first board and the second board through a soldering process.

### CLAIM OF PRIORITY

This application claims priority under 35 U.S.C. § 119 to an application entitled “Method for Fabricating Electronic Circuit Module and Integrated Circuit Device and Electronic Circuit Module Using the Method” filed in the Korean Intellectual Property Office on Aug. 9, 2005 and assigned Serial No. 2005-72752, the contents of which are incorporated herein by reference.

### BACKGROUND OF THE INVENTION

1. Field of the Invention

The present invention generally relates to an electronic circuit module in which a plurality of devices are stacked and a method for fabricating the same. More particularly, the present invention relates to a miniaturized electronic circuit module and a method for fabricating the same.

2. Description of the Related Art

With a distribution of portable digital devices and various digital media, multi-functional miniaturized components, electronic circuit modules, and optical integrated circuits are necessary in the modern multi media applications. To this end, a number of devices integrated in a board must be increased. In recent digital devices, Radio Frequency (RF) components for communication are embedded so that capacitance increases inversely proportional to the size of a circuit module.

An embedded Printed Circuit Board (PCB) has been suggested as a means for minimizing the volume of a digital device with a large-capacitance capacitor. In the embedded PCB, a resistor can accommodate most resistances, but the surface mounting of an additional capacitor must be performed to secure the capacitance at a desired level.

### SUMMARY OF THE INVENTION

It is, therefore, an object of the present invention to provide a circuit module that can satisfy a demand for a large-capacitance capacitor and can be applied to a miniaturized product, and a method for fabricating the circuit module.

According to one aspect of the present invention, there is provided an electronic circuit module including a first board and a second board having printed circuit patterns formed on their facing surfaces, and an electronic device disposed between the first board and the second board and having electrodes connected to the first board and the second board through soldering.

### BRIEF DESCRIPTION OF THE DRAWINGS

The above features and advantages of the present invention will become more apparent from the following detailed description when taken in conjunction with the accompanying drawings in which:

FIGS. 1A through 1D sequentially illustrate the occurrence of a tombstone phenomenon during the integration through a soldering process;

FIGS. 2A through 2E illustrate a process of fabricating an electronic circuit module according to a first embodiment of the present invention; and

FIGS. 3A through 3D illustrate a process of fabricating an integrated circuit device according to a second embodiment of the present invention.

### DETAILED DESCRIPTION OF THE INVENTION

Embodiments of the present invention will now be described in detail with reference to the annexed drawings. For the purposes of clarity and simplicity, a detailed description of known functions and configurations incorporated herein has been omitted for conciseness.

In the embodiment, for easiness in integration and fabrication of an electronic circuit module, soldering is used.

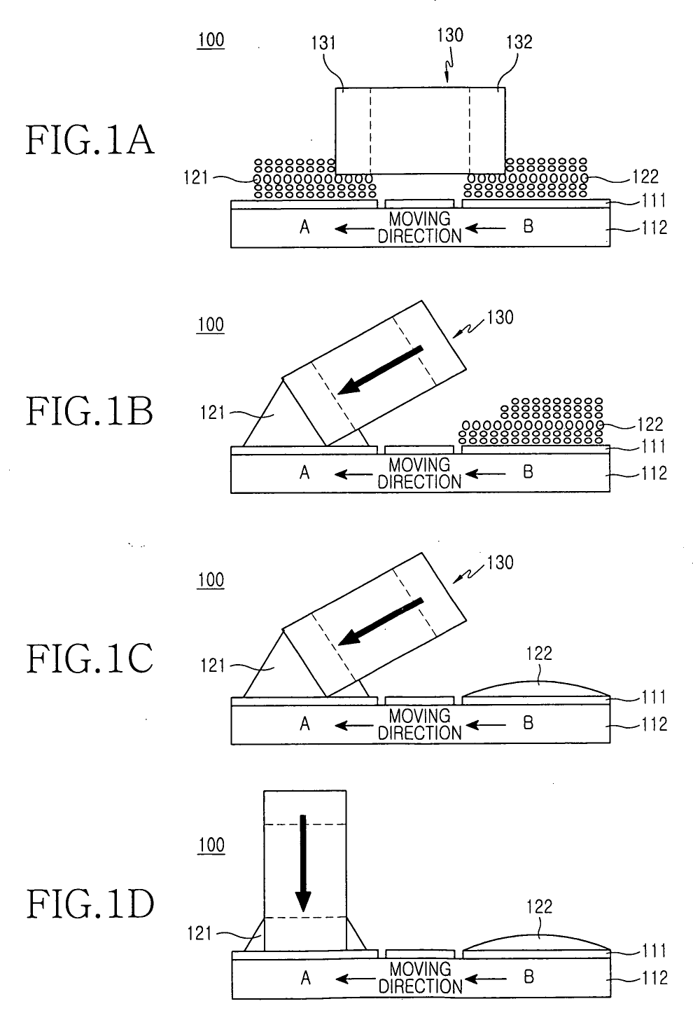

FIGS. 1A through 1D illustrate the occurrence of a tombstone phenomenon during the integration process through soldering. In FIGS. 1A through 1D, due to the unbalance of a melting heat during the integration of a device 130 including at least two electrodes 131 and 132, the electrode 132 at one end of the device 130 is not bonded to a board 112, and the electrode 131 at the other end of the device 130 gradually moves perpendicularly to a printed circuit 111 formed on the board 112 and then soldered to the printed circuit 111. As the use of small-size chips such as 1005 and 0603 increases, the tombstone phenomenon often occurs.

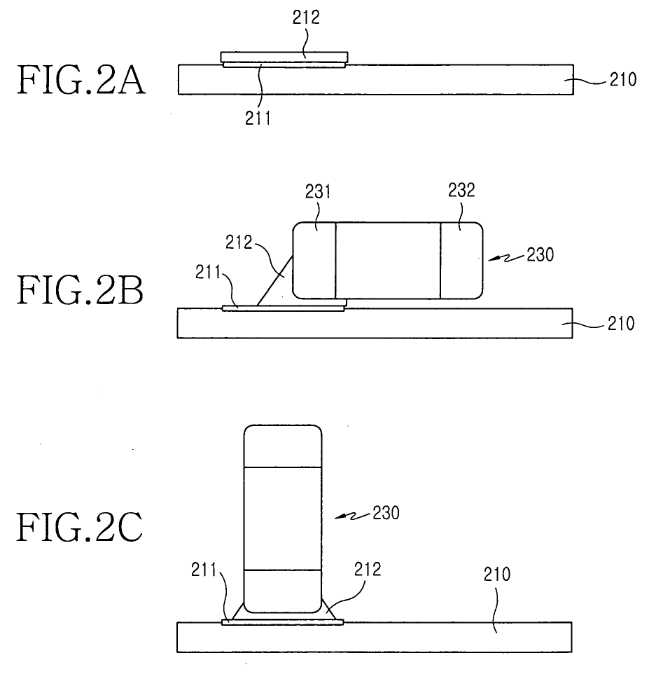

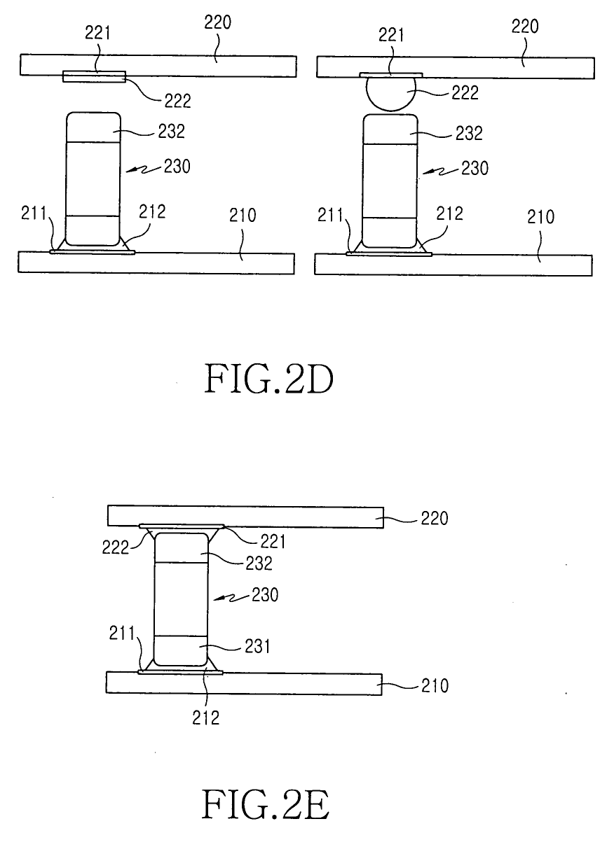

Briefly, FIGS. 2A through 2E illustrate the process of fabricating an electronic circuit module according to a first embodiment of the present invention, in which the tombstone phenomenon illustrated in FIGS. 1A through 1D is used. The electronic circuit module illustrated in FIGS. 2A through 2E includes a first board 210 having a top surface in which a circuit pattern 211 is formed, an electronic device 230 having at least two electrodes 231 and 232 in which the electrode 231 at one end of the electronic device 230 is electrically connected to the first board 210 through a tombstone arrangement, and a second board 220 to which the electrode 232 at the other end of the electronic device 230 is electrically connected through a soldering process.

Hereinafter, a process of fabricating the electronic circuit module will be described in details with reference to FIGS. 2A through 2E.

FIG. 2A illustrates a first step of forming the circuit pattern 211 on the top surface of the first board 210, in which a solder 212 for performing the soldering on the circuit pattern 211 of the first board 210 is formed.

FIG. 2B illustrates a second step of electrically connecting one of the electrodes 231 and 232 at one end of the electronic device 230, e.g., the electrode 231, to the circuit pattern 211. FIG. 2C illustrates a step of heating the solder 212 on which the electrode 231 is placed for the artificial tombstone arrangement of the electronic device 230.

FIGS. 2D and 2E illustrate a third step of electrically connecting the electrode 232, which is not connected to the first board 210, to the second board 220. FIG. 2D illustrates a step of forming a circuit pattern 221 on the second board 220 and a solder 222 for performing the soldering on the circuit pattern 221, in which the second board 220 having the solder 222 formed therein is heated for the soldering between the electrode 232 and the second board 220. The solder 222 may be formed by a solder screen printing process as illustrated in FIG. 2D or may be a solder ball.

FIG. 2E illustrates the electronic circuit module fabricated through the first through third steps. As shown, the electrodes 231 and 232 at both ends of the electronic device 230 are connected to the first board 210 and the second board 220, respectively. A gap between the first board 210 and the second board 220 may be determined according to the capacity of the electronic device 230. In other words, after the circuit patterns 211 and 221 are formed on the first board 210 and the second board 220, the gap between the first board 210 and the second board 220 are selectively adjusted according to the type and capacity of the electronic device 230. For example, when the electronic device 230 is a condenser, its capacitance may be adjusted. When the electronic device 230 is a resistor, its resistance may be adjusted. The electronic device 230 is a passive component known to those skilled in the art, such as SMD chip 0402, 0603, 1005, or 2012.

The electronic device 230 to be arranged using the tombstone phenomenon through screen printing, chip mounting, and reflow can be placed on the first board 210 and the second board 220. A Surface Mounting Device (SMD) or Bonder may be used as resin.

In the present invention, a fine gap adjustment is allowed through the foregoing steps. For example, when the electronic device 230 is 0402, the gap between the first board 210 and the second board 220 may be adjusted to 400 μm with a tolerance range of ±20 μm. When the electronic device 230 is 0603, the gap between the first board 210 and the second board 220 may be adjusted to 600 μm with a tolerance range of +30 μm. When the electronic device 230 is 1005, the gap between the first board 210 and the second board 220 may be adjusted to 1000 μm with a tolerance range of ±100 μm.

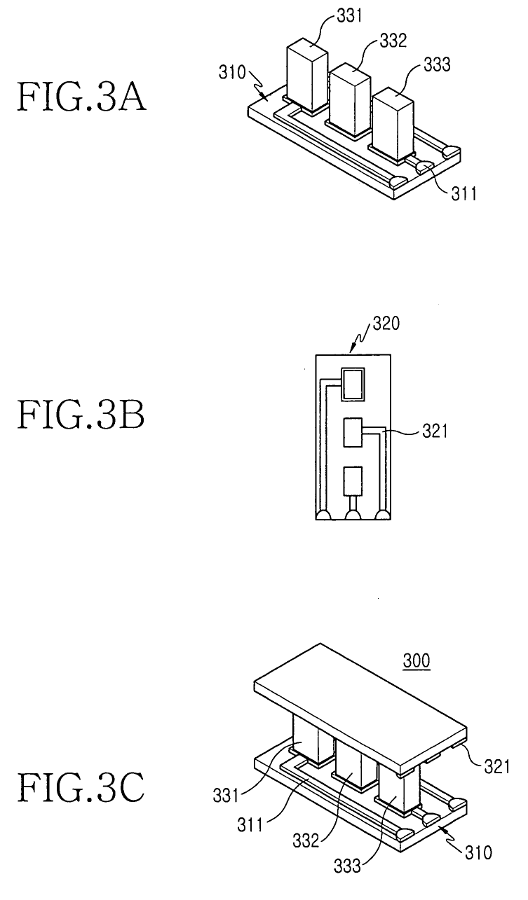

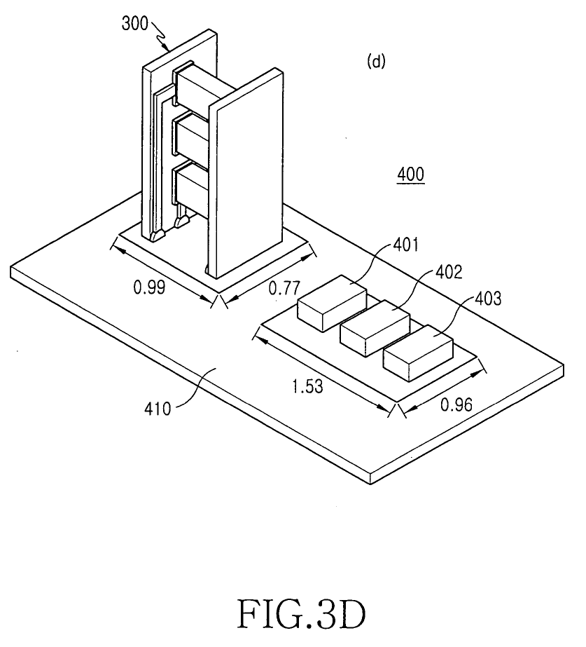

FIGS. 3A through 3D illustrate the process of fabricating an integrated circuit device according to a second embodiment of the present invention. In particular, FIG. 3(a) through 3(c) illustrate a process of fabricating an electronic circuit module 300 and the fabricated electronic circuit module 300. FIG. 3(d) illustrates a fabricated integrated circuit device 400.

Briefly, the process of fabricating the integrated circuit device 400 in which the electronic circuit module 300 according to the second embodiment includes a first step of forming the electronic circuit module 300, a second step of forming an integrated circuit pattern on a main board 410, a third step of electrically connecting one end of the electronic circuit module 300 to a corresponding portion of the integrated circuit pattern, and a fourth step of integrating a plurality of passive devices 401, 402, and 403 on the main board 410.

In the first step, the electronic circuit module 300 is formed through a tombstone arrangement with at least one electronic devices 331, 332, and 333 between a first board 310 and a second board 320. Circuit patterns 311 and 321 are formed on facing surfaces of the first board 310 and the second board 320. The first step includes first through third sub-steps.

In the first sub-step, the circuit board 311 is formed on the first board 310. In the second sub-step, one of at least two electrodes of each of the electronic devices 331 through 333 is electrically connected to the circuit pattern 311 through a tombstone arrangement.

In the third sub-step, the other electrode of each of the electronic devices 331 through 333 is electrically connected to the second board 320, thus completing the electronic circuit module 300.

In the second step, the integrated circuit pattern is formed on the main board 410. In the third step, one end of the electronic circuit module 300 is electrically connected to a corresponding portion of the integrated circuit pattern. In the fourth step, the plurality of passive devices 401 through 403 is integrated on the main board 410.

As described above, an electronic circuit module according to the present invention can be applied to a device that requires a high-integration mounting, and also a large-capacitance capacitor can be easily integrated in the electronic circuit module. Further, a low-cost process can be implemented by using general-purpose components, and a gap between devices can be finely adjusted.

While the present invention has been shown and described with reference to preferred embodiments thereof, it will be understood by those skilled in the art that various changes in form and details may be made therein without departing from the spirit and scope of the invention.

What is claimed is:

1. An electronic circuit module comprising:
a first board and a second board having printed circuit patterns formed thereon; and
an electronic device disposed between the first board and the second board and having a plurality of electrodes coupled to the first board and the second board through a soldering.

2. The electronic circuit module of claim 1, wherein the electronic device comprises the plurality of electrodes that are symmetrically disposed at both ends of the electronic device and the electrode at the other side, which is not connected to the first board in soldering to the first board, is arranged toward the second board.

3. An electronic circuit module comprising:
a first board having a circuit pattern formed on its top surface;
an electronic device having at least two electrodes, one of which at one side is electrically coupled to the first board through a tombstone arrangement; and
a second board to which the electrode at the other side is electrically coupled through soldering.

4. A method for fabricating an electronic circuit module, the method comprising the steps of:
forming a circuit pattern on the top surface of a first board;
electrically coupling one of at least two electrodes of an electronic device to the circuit pattern; and
electrically coupling the electrode at the other side of the electronic device, which is not coupled to the first board, to a second board.

5. The method of claim 4, wherein the electrodes of the electronic device are electrically coupled to the first board and the second board through soldering.

6. The method of claim 4, wherein the electronic device is disposed between the first board and the second board and the electrodes of the electronic device are electrically coupled to the first board and the second board.

7. The method of claim 4, wherein the electrode at the other side of the electronic device, which is not coupled to the first board in soldering to the first board, is tombstone-arranged and perpendicularly to the first board.

8. A method for fabricating an integrated circuit device in which an electronic circuit module is integrated, the method comprising the steps of:
forming an electronic circuit module in which at least one electronic devices are tombstone-arranged between a first board and a second board having circuit patterns formed on their facing surfaces;
forming an integrated circuit pattern on a main board;
electrically coupling one end of the electronic circuit module to a corresponding portion of the integrated circuit pattern; and
integrating a plurality of passive devices on the main board.

9. The method of claim 8, wherein the step of forming the electronic circuit module comprises the steps of:
forming the circuit pattern on the top surface of the first board;
electrically coupling one of at least two electrodes of each of the electronic devices to the circuit pattern; and
electrically coupling the electrode at the other side, which is not coupled to the first board, to the second board.
